(19) United States
(12) Patent Application Publication
(10) Pub. No.: US 2026/0088842 A1
(43) Pub. Date: Mar. 26, 2026

(54) PHASED ARRAY TRANSMITTER, TRANSMISSION METHOD, AND COMPUTER-READABLE MEDIUM

(71) Applicant: NEC Corporation, Tokyo (JP)

(72) Inventor: Masaaki TANIO, Tokyo (JP)

(73) Assignee: NEC Corporation, Tokyo (JP)

(21) Appl. No.: 19/314,217

(22) Filed: Aug. 29, 2025

(30) Foreign Application Priority Data
Sep. 22, 2024 (JP) 2024-157213
Aug. 1, 2025 (JP) 2025-129081

(51) Int. Cl. H04B 1/04; H03F 1/32; H04L 25/49

(52) U.S. Cl. CPC H04B 1/0475; H03F 1/3241; H04L 25/49

(57) ABSTRACT

An object of the present disclosure is to appropriately perform compensation for nonlinear distortion. Provided is a phased array transmitter including a k-th distortion compensation unit that outputs a k-th coefficient group by a k-th neural network model based on time-series signals of first to k (k is an integer of 1 to N, and N is an integer equal to or more than 2) input signals, and outputs, as a k-th output signal, a value obtained by multiplying each value included in the time-series signal of the k-th input signal by each coefficient included in the k-th coefficient group and adding the multiplied values, in which the k-th output signal is subjected to phase control and amplification relevant to each of a plurality of antennas, and is radiated from the plurality of antennas wirelessly.

### INCORPORATION BY REFERENCE

This application is based upon and claims the benefit of priority from Japanese patent application No. 2024-157213, filed on Sep. 11, 2024, and Japanese patent application No. 2025-129081, filed on Aug. 1, 2025, the disclosure of which is incorporated herein in its entirety by reference.

### TECHNICAL FIELD

The present disclosure relates to a phased array transmitter, a transmission method, and a program.

### BACKGROUND ART

PTL 1 discloses a technique related to neural network-based digital pre-distortion (DPD). PTL 1 includes a digital pre-distortion (DPD) actuator for receiving an input signal associated with a nonlinear component of a radio frequency (RF) transceiver and outputting a pre-distorted signal. The DPD actuator includes a basis function-based actuator for performing a first DPD operation using a set of basis functions associated with a first nonlinear characteristic of the nonlinear component. The DPD actuator further includes a neural network-based actuator for performing a second DPD operation using a first neural network associated with a second nonlinear characteristic of the nonlinear component.

### CITATION LIST

### Patent Literature

PTL 1: JP 2024-520936 A

### SUMMARY

However, in the technique described in PTL 1, for example, there is a case where compensation for nonlinear distortion cannot be appropriately executed.

In view of the above-described problems, an example object of the present disclosure is to provide a technique capable of appropriately performing compensation for nonlinear distortion.

In a first example aspect according to the present disclosure, there is provided a phased array transmitter including an input unit that inputs a time-series signal of a first input signal and a time-series signal of a second input signal, a first distortion compensation unit that outputs a first coefficient group by a first neural network model based on the time-series signal of the first input signal and the time-series signal of the second input signal, and outputs, as a first output signal, a value obtained by multiplying each value included in the time-series signal of the first input signal by each coefficient included in the first coefficient group and then adding the multiplied values, and a second distortion compensation unit that outputs a second coefficient group by a second neural network model based on the time-series signal of the first input signal and the time-series signal of the second input signal, and outputs, as a second output signal, a value obtained by multiplying each value included in the time-series signal of the second input signal by each coefficient included in the second coefficient group and adding the multiplied values. The first output signal and the second output signal are subjected to phase control and amplification in accordance with each of a plurality of antennas, and are radiated through the plurality of antennas in a wireless manner.

In a second example aspect according to the present disclosure, there is provided a transmission method for causing a phased array transmitter to execute inputting a time-series signal of a first input signal and a time-series signal of a second input signal, outputting a first coefficient group by a first neural network model based on the time-series signal of the first input signal and the time-series signal of the second input signal, and outputting, as a first output signal, a value obtained by multiplying each value included in the time-series signal of the first input signal by each coefficient included in the first coefficient group and then adding the multiplied values, and outputting a second coefficient group by a second neural network model based on the time-series signal of the first input signal and the time-series signal of the second input signal, and outputting, as a second output signal, a value obtained by multiplying each value included in the time-series signal of the second input signal by each coefficient included in the second coefficient group and adding the multiplied values. The first output signal and the second output signal are subjected to phase control and amplification in accordance with each of a plurality of antennas, and are radiated through the plurality of antennas in a wireless manner.

In a third example aspect according to the present disclosure, there is provided a program for causing a computer of a phased array transmitter to execute inputting a time-series signal of a first input signal and a time-series signal of a second input signal, outputting a first coefficient group by a first neural network model based on the time-series signal of the first input signal and the time-series signal of the second input signal, and outputting, as a first output signal, a value obtained by multiplying each value included in the time-series signal of the first input signal by each coefficient included in the first coefficient group and then adding the multiplied values, and outputting a second coefficient group by a second neural network model based on the time-series signal of the first input signal and the time-series signal of the second input signal, and outputting, as a second output signal, a value obtained by multiplying each value included in the time-series signal of the second input signal by each coefficient included in the second coefficient group and adding the multiplied values. The first output signal and the second output signal are subjected to phase control and amplification in accordance with each of a plurality of antennas, and are radiated through the plurality of antennas in a wireless manner.

According to one aspect, an example advantage is that compensation for nonlinear distortion can be appropriately executed.

### BRIEF DESCRIPTION OF DRAWINGS

The above and other aspects, features and advantages of the present disclosure will become more apparent from the following description of certain exemplary embodiments when taken in conjunction with the accompanying drawings, in which:

FIG. 1 is a diagram illustrating an example of a configuration of a phased array transmitter according to an example embodiment;

FIG. 2 is a diagram illustrating an example of a configuration of a beamforming matrix according to an example embodiment;

FIG. 3 is a diagram illustrating an example of a configuration of a beamforming matrix according to an example embodiment;

FIG. 4 is a diagram illustrating a hardware configuration example of a distortion compensation unit of the phased array transmitter according to the example embodiment;

FIG. 5 is a flowchart illustrating an example of processing of a distortion compensation unit according to the example embodiment;

FIG. 6 is a diagram illustrating an example of processing of the distortion compensation unit according to the example embodiment;

FIG. 7 is a diagram illustrating an example of processing of the distortion compensation unit according to the example embodiment; and

FIG. 8 is a diagram illustrating an example of processing of the distortion compensation unit according to the example embodiment.

### EXAMPLE EMBODIMENTS

The principles of the present disclosure will be described with reference to several exemplary example embodiments. It is to be understood that the example embodiments have been described for purposes of illustration only and will aid those skilled in the art in understanding and carrying out the present disclosure without suggesting limitations on the scope of the present disclosure. The disclosure described in the present description is implemented in various methods other than those described below.

In the following description and claims, unless defined otherwise, all technical and scientific terms used in the present specification have the same meaning as commonly understood by those skilled in the art of the technical field to which the present disclosure belongs.

Hereinafter, example embodiments of the present disclosure will be described with reference to the drawings. Each of the drawings is merely an example to illustrate one or more example embodiments. Each of the drawings is not associated with only one specific example embodiment, but may be associated with one or more other example embodiments. As those of ordinary skill in the art will appreciate, various features or steps described with reference to any one of the drawings may be combined with features or steps illustrated in one or more other figures, for example, to create an example embodiment that is not explicitly illustrated or described. All of the features or steps illustrated in any one of the figures to explain illustrative example embodiments are not necessarily mandatory, and some features or steps may be omitted. The order of the steps described in any of the drawings may be changed as appropriate.

### First Example Embodiment

### Configuration

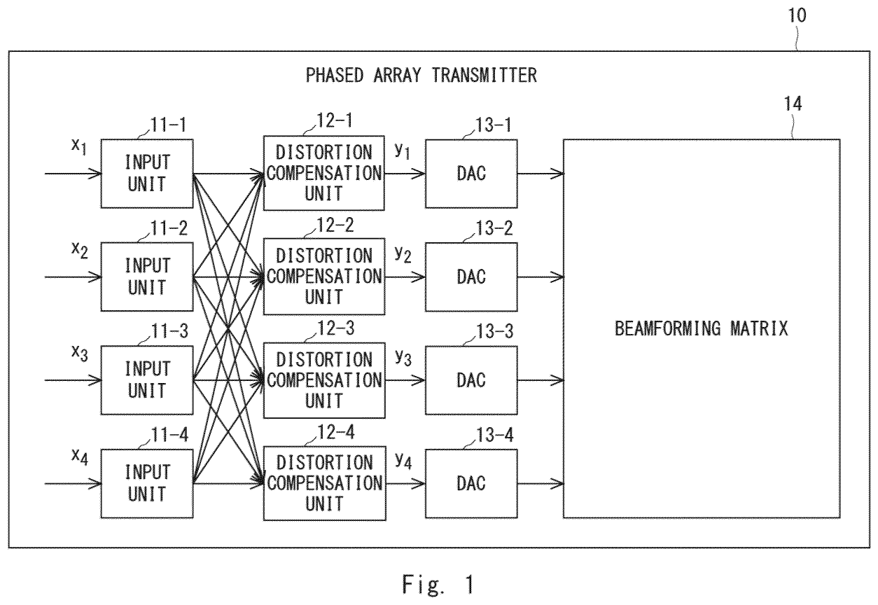

A configuration of a phased array transmitter 10 according to an example embodiment will be described with reference to FIG. 1. FIG. 1 is a diagram illustrating an example of a configuration of the phased array transmitter 10 according to the example embodiment. FIGS. 1 to 3 illustrate an example in which N is 4, but N in the present disclosure is not limited to 4 and may be an integer equal to or more than 2. The phased array transmitter 10 may perform communication in a multi-band (and multi-user) in which a carrier frequency is different for each signal, or may perform communication in a single band (and multi-user) using the same band (carrier frequency).

The phased array transmitter 10 has input units 11-1 to 11-N (in the present disclosure, N is an integer equal to or more than 2) (hereinafter, in a case where there is no need to distinguish, it is also simply referred to as “input unit 11” as appropriate). The phased array transmitter 10 includes distortion compensation units (DPDs: digital predistortions) 12-1 to 12-N (hereinafter, in a case where there is no need to distinguish, it is also simply referred to as a “distortion compensation unit 12” as appropriate).

The phased array transmitter 10 includes a digital-to-analog converter (D/A converter) 13-1 to 13-N (hereinafter, in a case where there is no need to distinguish, it is also simply referred to as “DAC 13” as appropriate). The phased array transmitter 10 also has a beamforming matrix (phased array antenna) 14.

Each of the input units 11-1 to 11-N inputs (acquires) digital data of each of the input signals x₁ to x_{N} which are data to be wirelessly transmitted from the phased array transmitter 10. For example, the input unit 11-1 acquires the input signal x₁, the input unit 11-2 acquires the input signal x₂, and the input unit 11-N acquires the input signal x_{N}.

The distortion compensation unit 12-k (in the present disclosure, k is an integer from 1 to N) generates an output signal yₖ in which signal interference due to nonlinear distortion of an amplifier arranged for each antenna is canceled based on the input signals x₁ to x_{N} acquired by the input units 11-1 to 11-N, and outputs the output signal yₖ to the DAC 13-k. More specifically, the distortion compensation unit 12-k outputs a k-th coefficient group by a k-th neural network model (k-th learned model) based on the time-series signal of each of the input signals x₁ to x_{N}. Then, the distortion compensation unit 12-k outputs a value obtained by multiplying each value included in the time-series signal of the input signal xₖ (k-th input signal) by each coefficient included in the k-th coefficient group and adding the multiplied values as an output signal yₖ (k-th output signal). Therefore, output signals y₁ to y_{N} are generated by the distortion compensation units 12-1 to 12-N.

The DAC 13-k converts the data from the distortion compensation unit 12-k into an analog signal and outputs the analog signal to the beamforming matrix 14. The beamforming matrix 14 phase-controls and amplifies the output signals y₁ to y_{N} relevant to the plurality of antennas, and radiates the output signals y₁ to y_{N} wirelessly from the plurality of antennas. As a result, the nonlinear distortion occurs in the output signals y₁ to y_{N} to which the inverse characteristic of the signal interference due to the nonlinear distortion of the amplifier arranged for each antenna is added, whereby each of the original input signals x₁ to x_{N} is transmitted to a receiver (not illustrated) by a radio wave. An IF frequency signal in a frequency band lower than the RF frequency of the target may be output to the DAC 13-k. In that case, a frequency mixer and a band pass filter may be arranged after the DAC 13-k, and conversion from IF to RF may be performed in the frequency mixer. Then, in the band pass filter, signal components other than a desired RF component generated in the frequency mixer may be removed, and a desired RF signal may be output.

### Beamforming Matrix 14

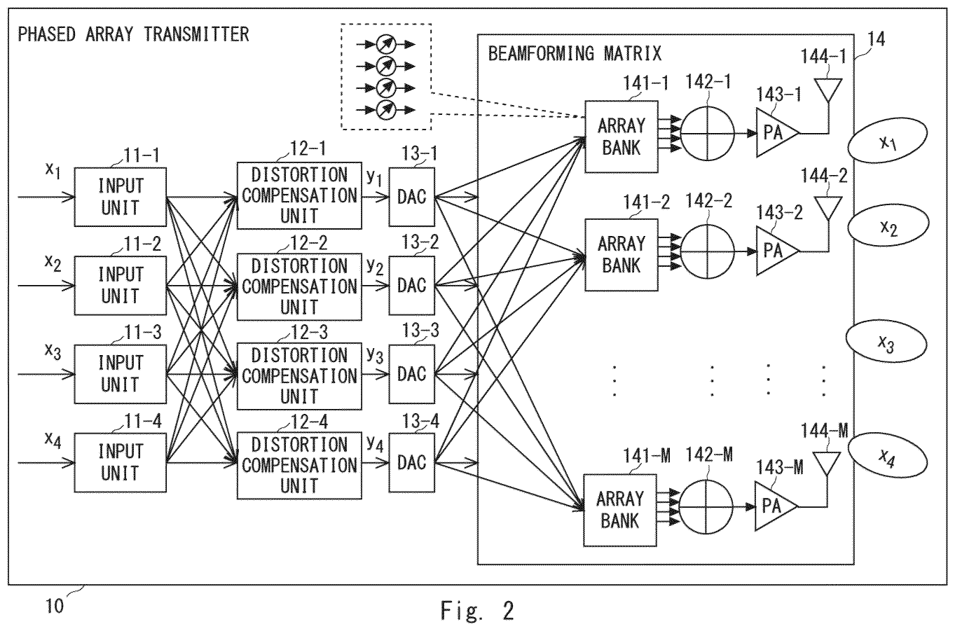

FIG. 2 is a diagram illustrating an example of a configuration of the beamforming matrix 14 according to the example embodiment. In the example of FIG. 2, the beamforming matrix 14 has array bank 141-1 to 141-M, adders 142-1 to 142-M, amplifiers (PA, power amplifier) 143-1 to 143-M, and antennas 144-1 to 144-M. In the present disclosure, M is an integer equal to or more than 2. For example, M may be an integer greater than N.

In the example of FIG. 2, the array bank 141-m (in the present disclosure, m is an integer from 1 to M) controls the phases of the output signals y₁ to y_{N} after analog conversion by a phase shifter, and outputs the signals to the adder 142-m. The adder 142-m adds y₁ to y_{N} whose phases are controlled, and outputs the result to the amplifier 143-m. The amplifier 143-m amplifies the amplitude (intensity) of the signal from the adder 142-m and outputs the amplified signal to the antenna 144-m. The antenna 144-m transmits a signal from the amplifier 143-m to a receiver (not illustrated) by a radio wave. The beamforming matrix 14 illustrated in FIG. 2 may be referred to as a full array configuration. In the phase shifter, the amplitude value may be controlled in addition to the phase in order to enhance the accuracy of the beam control.

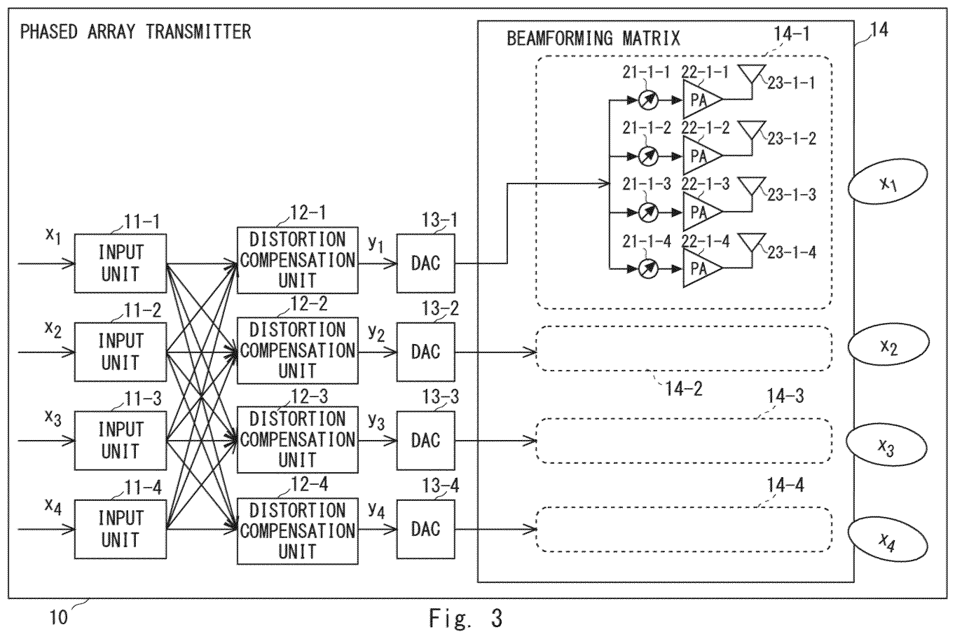

FIG. 3 is a diagram illustrating another example of the configuration of the beamforming matrix 14 according to the example embodiment. In the example of FIG. 3, the beamforming matrix 14 has sub-matrices 14-1 to 14-L (in the present disclosure, L is an integer equal to or more than 2). The sub-matrices 14-1 to 14-L transmit the input signals x₁ to x_{N} to a receiver (not illustrated) by radio waves. In the example of FIG. 3, the detailed configuration is illustrated only for the sub-matrix 14-1, but each of the sub-matrices 14-2 to 14-L has the same configuration as the sub-matrix 14-1. The sub-matrix 14-k includes phase shifters 21-k-1 to 21-k-L, amplifiers 22-k-1 to 22-k-L, and antennas 23-k-1 to 23-k-L.

In the example of FIG. 3, the sub-matrix 14-k controls the phase of the output signal yₖ after analog conversion by each of the phase shifters 21-k-1 to 21-k-L, and outputs the signal to the amplifiers 22-k-1 to 22-k-L. Each of the amplifiers 22-k-1 to 22-k-L amplifies the amplitude (intensity) of the signal from each of the phase shifters 21-k-1 to 21-k-L and outputs the amplified signal to each of the antennas 23-k-1 to 23-k-L. Each of the antennas 23-k-1 to 23-k-L transmits a signal from each of the amplifiers 22-k-1 to 22-k-L to a receiver (not illustrated) by a radio wave. The beamforming matrix 14 illustrated in FIG. 3 may be referred to as a sub-array configuration.

### Hardware Configuration of Distortion Compensation Unit 12

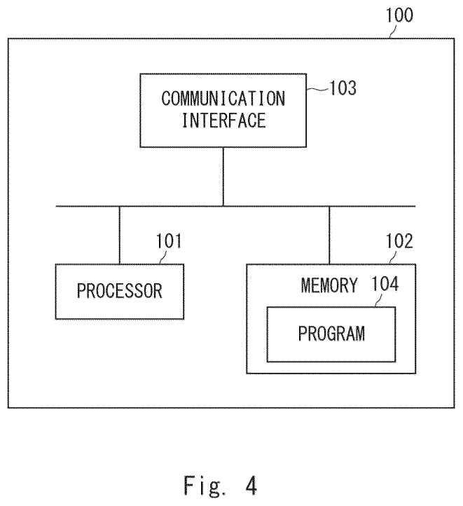

FIG. 4 is a diagram illustrating an exemplary hardware configuration of the distortion compensation unit 12 of the phased array transmitter 10 according to the example embodiment. In the example of FIG. 4, the distortion compensation unit 12 (computer 100) includes a processor 101, a memory 102, and a communication interface 103. These units may be connected by a bus or the like. The memory 102 stores at least a part of a program 104. The communication interface 103 includes an interface necessary for communication with other network elements.

In a case where the program 104 is executed by the cooperation of the processor 101, the memory 102, and the like, at least a part of processing according to the example embodiment of the present disclosure is performed by the computer 100. The memory 102 may be of any type. The memory 102 may be a non-transitory computer-readable storage medium, as a non-limiting example. The memory 102 may also be implemented using any suitable data storage technique such as a semiconductor-based memory device, a magnetic memory device and system, an optical memory device and system, a fixed memory, or a removable memory. Although only one memory 102 is illustrated in the computer 100, there may be several physically different memory modules in the computer 100. The processor 101 may be of any type. The processor 101 may include one or more of a general purpose computer, a dedicated computer, a microprocessor, a Digital Signal Processor (DSP), and a processor based on a multi-core processor architecture as a non-limiting example. The computer 100 may have a plurality of processors, such as an application specific integrated circuit chip that is temporally dependent on a clock that synchronizes the main processor.

Example embodiments of the present disclosure may be implemented in hardware or dedicated circuitry, software, logic, or any combination thereof. Some aspects may be implemented in hardware, while other aspects may be implemented in firmware or software that may be executed by a controller, a microprocessor or other computing devices.

The present disclosure also provides at least one computer program product tangibly stored on a non-transitory computer-readable storage medium. The computer program product includes computer-executable instructions, such as those included in a program module, and is executed on a device on a target real or virtual processor to perform the processes or methods of the present disclosure. The program module includes routines, programs, libraries, objects, classes, components, data structures, and the like that execute particular tasks or implement particular abstract data types. Functions of the program module may be combined or divided between the program modules as desired in various example embodiments. A machine-executable instruction of the program module can be executed in a local or distributed device. In a distributed device, program modules can be located on both local and remote storage media.

Program code for executing the methods of the present disclosure may be written in any combination of one or more programming languages. These program codes are provided to a processor or controller of a general purpose computer, a dedicated computer, or other programmable data processing devices. In a case where the program code is executed by the processor or controller, the functions/operations in the flowcharts and/or the implemented block diagrams are performed. The program code is executed entirely on the machine, partly on the machine, as a stand-alone software package, partly on the machine, partly on a remote machine, or entirely on the remote machine or the server.

The program can be stored and supplied to the computer using various types of non-transitory computer-readable media. The non-transitory computer-readable medium includes various types of tangible recording media. Examples of the non-transitory computer-readable medium include a magnetic recording medium, a magneto-optical recording medium, an optical disc medium, and a semiconductor memory. Examples of the magnetic recording medium include a flexible disk, a magnetic tape, and a hard disk drive. Examples of the magneto-optical recording medium include a magneto-optical disk. Examples of the optical disc medium include a Blu-ray disc, a compact disc (CD)-read only memory (ROM), a CD-recordable (R), and a CD-rewritable (RW). Examples of the semiconductor memory include a solid state drive, a mask ROM, a programmable ROM (PROM), an erasable PROM (EPROM), a flash ROM, and a random access memory (RAM). The program may be supplied to the computer using various types of transitory computer-readable media. Examples of the transitory computer-readable media include electric signals, optical signals, and electromagnetic waves. The transitory computer-readable media can provide the program to the computer via a wired communication line such as an electric wire and optical fibers or a wireless communication line.

### Processing

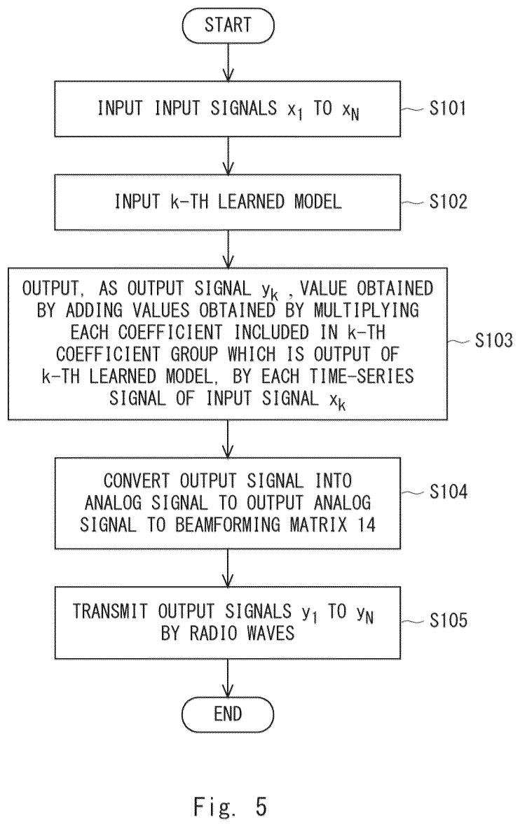

Next, an example of processing of the distortion compensation unit 12 according to the example embodiment will be described with reference to FIGS. 5 to 7. FIG. 5 is a flowchart illustrating an example of processing of the distortion compensation unit 12 according to the example embodiment.

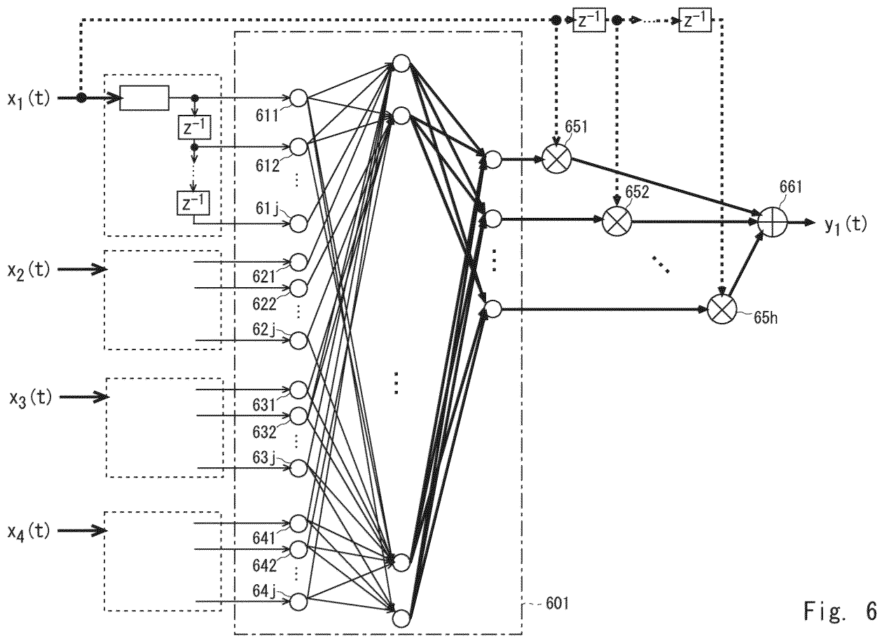

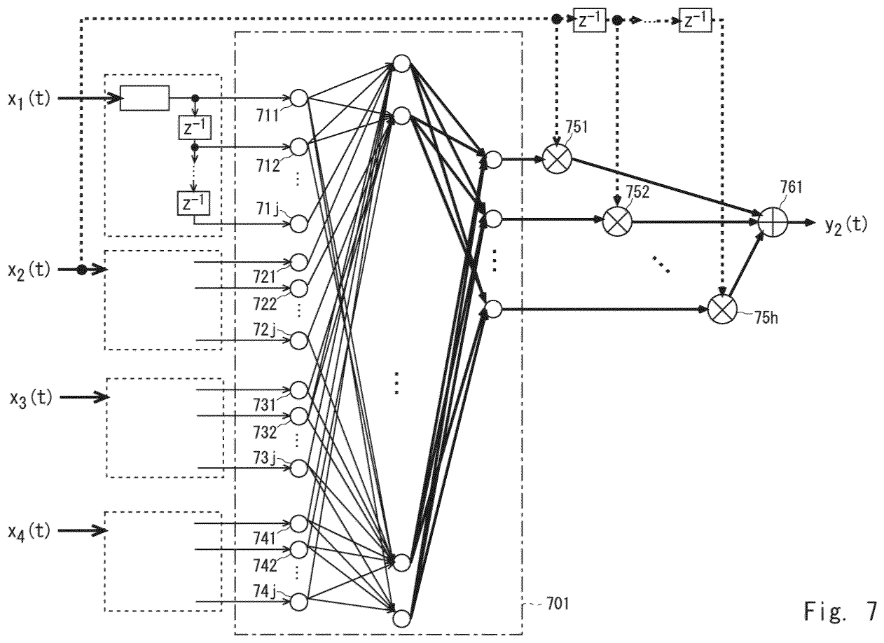

FIGS. 6 and 7 are diagrams illustrating an example of processing of the distortion compensation unit 12 according to the example embodiment. The processing of FIG. 5 may be executed at each time point in a case where data is wirelessly transmitted.

In step S101, each of the input units 11-1 to 11-N inputs (acquires) digital data of each of the input signals x₁ to x_{N} wirelessly transmitted from the phased array transmitter 10.

Subsequently, each distortion compensation unit 12-k inputs each data based on the input signals x₁ to x_{N} to a learned model (k-th learned model) for generating a k-th transmission signal (step S102). Here, as illustrated in FIGS. 6 to 7, the distortion compensation unit 12-k may use the signal (time-series signal) at each time point up to the present of each of the input signals x₁ to x_{N} as each input data (each explanatory variable) of the k-th learned model. Each learned model may be preset in the phased array transmitter 10.

In the example of FIG. 6, the distortion compensation unit 12-1 sets, as first input data of a first learned model 601, a value 611 which is a result of the specific operation of the value x₁(t) of the current time t of the input signal x₁. Details of the specific operation will be described later.

The distortion compensation unit 12-1 sets, as second input data of the first learned model 601, a value 612 which is a result of specific operation of a value x₁(t−1) at a time point before the current time t of the input signal x₁ by a specific period. The distortion compensation unit 12-1 sets, as j-th input data of the first learned model 601, a value 61j which is a result of specific operation of a value x₁(t−j) at a time point j (j is an integer equal to or more than 2) times before the current time t of the input signal x₁ in a specific period.

For the input signal x₂, similarly to the case of the input signal x₁, the distortion compensation unit 12-1 sets, as (j+1)th input data, a value 621 which is a result of the specific operation of the value x₂(t). The distortion compensation unit 12-1 sets, as (j+2)th input data, a value 622 which is a result of the specific operation of the value x₂(t−1). The distortion compensation unit 12-1 sets, as (j+j)th input data, a value 62j which is a result of the specific operation of the value x₂(t−j).

Similarly to the case of the input signal x₁, for the input signal x₃, the distortion compensation unit 12-1 also sets, as (j+j+1)th input data, the value 631 which is a result of the specific operation of the value x₃(t). The distortion compensation unit 12-1 sets, as (j+j+2)th input data, a value 632 which is a result of the specific operation of the value x₃(t−1). The distortion compensation unit 12-1 sets, as (j+j+j)th input data, a value 63j which is a result of the specific operation of the value x₃(t−j).

For the input signal x₄, similarly to the case of the input signals x₁ to x₃, the distortion compensation unit 12-1 sets, as (j+j+j+1)th input data, a value 641 which is a result of the specific operation of the value x₄(t). The distortion compensation unit 12-1 sets, as (j+j+j+2)th input data, a value 642 which is a result of the specific operation of the value x₄(t−1). The distortion compensation unit 12-1 sets, as (j+j+j+j)th input data, a value 64j which is a result of the specific operation of the value x₄(t−j).

In the example of FIG. 7, the distortion compensation unit 12-2 sets, as the first input data of a second learned model 701, a value 711 which is a result of the specific operation of the value x₁(t) of the current time t of the input signal x₁. The distortion compensation unit 12-2 sets, as second input data of the second learned model 701, a value 712 that is a result of specific operation of a value x₁(t−1) at a time point before the current time t of the input signal x₁ by a specific period. The distortion compensation unit 12-2 sets, as j-th input data of the second learned model 701, a value 71j which is a result of specific operation of values x₁(t−j) at a time point j times before the current time t of the input signal x₁ in the specific cycle.

For the input signal x₂, similarly to the case of the input signal x₁, the distortion compensation unit 12-2 sets, as (j+1)th input data, a value 721 which is a result of the specific operation of the value x₂(t). The distortion compensation unit 12-2 sets, as (j+2)th input data, a value 722 which is a result of the specific operation of the value x₂(t−1). The distortion compensation unit 12-2 sets, as (j+j)th input data, a value 72j which is a result of the specific operation of the value x₂(t−j).

Similarly to the case of the input signal x₁, for the input signal x₃, the distortion compensation unit 12-2 also sets, as (j+j+1)th input data, the value 731 which is a result of the specific operation of the value x₃(t). The distortion compensation unit 12-2 sets, as (j+j+2)th input data, a value 732 which is a result of the specific operation of the value x₃(t−1). The distortion compensation unit 12-2 sets, as (j+j+j)th input data, a value 73j which is a result of the specific operation of the value x₃(t−j).

For the input signal x₄, similarly to the case of the input signals x₁ to x₃, the distortion compensation unit 12-2 sets, as (j+j+j+1)th input data, a value 741 which is a result of the specific operation of the value x₄(t). The distortion compensation unit 12-2 sets, as (j+j+j+2)th input data, a value 742 which is a result of the specific operation of the value x₄(t−1). The distortion compensation unit 12-2 sets, as (j+j+j+j)th input data, a value 74j which is a result of the specific operation of the value x₄(t−j). The distortion compensation units 12-3 to 12-N are similar to the distortion compensation units 12-1 and 12-2.

### Specific Operation

The distortion compensation unit 12-k may calculate, for example, the square of the amplitude of the signal as the above-described specific operation. In this case, for example, the value (for example, the value 611 in FIG. 6 and the value 711 in FIG. 7) as the first input data of the k-th learned model is |x₁(t)|², and the value (for example, the value 612 in FIG. 6 and the value 712 in FIG. 7) as the second input data is |x₁(t−1)|². The distortion compensation unit 12-k may calculate, for example, the amplitude of the signal as the above-described specific operation. In this case, for example, the value (for example, the value 611 in FIG. 6 and the value 711 in FIG. 7) as the first input data of the k-th learned model is |x₁(t)|, and the value (for example, the value 612 in FIG. 6 and the value 712 in FIG. 7) as the second input data is |x₁(t−1)|.

The distortion compensation unit 12-k may calculate at least one of, for example, a real part of a signal, an imaginary part of a signal, a square of a real part of a signal, a square of an imaginary part of a signal, and a multiplication value between a real part and an imaginary part of a signal, as the above-described specific operation.

The distortion compensation unit 12-k may calculate, for example, the square of the amplitude of the linear sum of the input signals x₁ to x_{N} as the above-described specific operation. In this case, for example, the value (for example, the value 611 in FIG. 6 and the value 711 in FIG. 7) as the first input data of the k-th learned model is |x₁(t)+w₂x₂(t)+. . . +w_{N}x_{N}(t)|², and the value (for example, the value 612 in FIG. 6 and the value 712 in FIG. 7) as the second input data is |x₁(t−1)+w₂x₂(t−1)+. . . +w_{N}x_{N}(t−1)|². w₂ to w_{N} are specific weighting factors. The distortion compensation unit 12-k may calculate the amplitude of the linear sum of the input signals x₁ to x_{N}, for example, as the above-described specific operation. In this case, for example, the value (for example, the value 611 in FIG. 6 and the value 711 in FIG. 7) as the first input data of the k-th learned model is |x₁(t)+w₂x₂(t)+. . . +w_{N}x_{N}(t)|, and the value (for example, the value 612 in FIG. 6 and the value 712 in FIG. 7) as the second input data is |x₁(t−1)+w₂x₂(t−1)+. . . +w_{N}x_{N}(t−1)|.

The distortion compensation unit 12-k may calculate, for example, an inner product or an outer product of the first input signal and the second input signal, in which the I signal and the Q signal of each input signal are regarded as separate components of a vector, as the above-described specific operation. In this case, for example, the value (for example, the value 611 in FIG. 6 and the value 711 in FIG. 7) to be the first input data of the k-th learned model is Real(x₁(t))×Real(x₂(t))+Imag(x₁(t))×Imag(x₂(t)), and the value (for example, the value 612 in FIG. 6 and the value 712 in FIG. 7) to be the second input data is Real(x₁(t−1))×Real(x₂(t−1))+Imag(x₁(t−1))×Imag(x₂(t−1)). Real(x) represents a real part of x, and Imag(x) represents an imaginary part of x.

The distortion compensation unit 12-k may calculate, for example, an amplitude value of a linear sum of different signals as the above-described specific operation. Examples of the above-described specific operation can be used in appropriate combination.

Subsequently, each distortion compensation unit 12-k of FIGS. 6 and 7 outputs, as the output signal yₖ, a value obtained by adding (summing) values obtained by multiplying each coefficient included in the k-th coefficient group, which is H (in the present disclosure, H is an integer equal to or more than 2) outputs of the k-th learned model, by the time-series signals at the H time points of the input signal xₖ to the DAC 13-k (step S103). As a result, each output signal yₖ to which the inverse characteristic of the signal interference due to the nonlinear distortion of the amplifier arranged for each antenna is added is output. Therefore, since the inverse characteristic along the physical model of the signal interference due to the nonlinear distortion of the amplifier arranged for each antenna can be effectively added, higher distortion compensation performance can be obtained with a smaller amount of operation. The value of H may be set in advance in the phased array transmitter 10, for example.

Here, as illustrated in FIGS. 6 to 7, the distortion compensation unit 12-k may add a value obtained by multiplying a time-series signal of the input signal xₖ by each output data (each objective variable) of the k-th learned model.

In the example of FIG. 6, the distortion compensation unit 12-1 performs multiplication 651 on the first output data of the first learned model 601 by the value x₁(t), and performs multiplication 652 on the second output data by the value x₁(t−1). Similarly, the distortion compensation unit 12-1 performs multiplication 65h on the h-th output data by the value x₁(t−h) for h, which is each integer equal to or more than 2 and equal to or less than H. Then, the distortion compensation unit 12-1 outputs a value obtained by performing addition 661 on the results of the multiplications 651 to 65h as the output signal y₁.

In the example of FIG. 7, the distortion compensation unit 12-2 performs multiplication 751 on the first output data of the second learned model 701 by the value x₂(t), and performs multiplication 752 on the second output data by the value x₂(t−1). Similarly, the distortion compensation unit 12-2 performs multiplication 75h on the h-th output data by the value x₂(t−h) for h, which is an integer equal to or less than H. Then, the distortion compensation unit 12-2 outputs a value obtained by performing addition 761 on the results of the multiplications 751 to 75h as the output signal y₂.

Similarly, the distortion compensation unit 12-k multiplies the first output data of the k-th learned model by the value xₖ(t), and multiplies the second output data by the value xₖ(t−1). Similarly, the distortion compensation unit 12-k multiplies the h-th output data by the value xₖ(t−h) for h, which is an integer equal to or more than 2 and equal to or less than H. Then, the distortion compensation unit 12-k outputs a value obtained by adding the results of the multiplications as the output signal yₖ.

Subsequently, the DAC 13-k converts the output signals y₁ to y_{N} from each distortion compensation unit 12 into analog signals and outputs the analog signals to the beamforming matrix 14 (step S104).

Subsequently, the beamforming matrix 14 performs phase control and amplification on the output signals y₁ to y_{N} relevant to the plurality of antennas, radiates the output signals y₁ to y_{N} from the plurality of antennas wirelessly, and transmits the output signals y₁ to y_{N} to a receiver (not illustrated) (step S105). As a result of mixing the output signals y₁ to y_{N} by the nonlinear distortion of the amplifier arranged for each antenna, radio waves of the original input signals x₁ to x_{N} are emitted. As a result, the receiver receives the original input signals x₁ to x_{N}.

### Example of Pruning Learned Model

Each distortion compensation unit 12-k may remove (prune) the connection of the reduced weight in the process of learning the k-th learned model. As a result, for example, the number of connections (the number of parameters) of the k-th learned model is reduced, and the amount of computation can be further reduced.

### Example of Updating Learned Model

Each distortion compensation unit 12-k may feed back a distortion compensation signal and update the k-th learned model. As a result, for example, the compensation of the nonlinear distortion can be more appropriately executed according to the nonlinear distortion of the actual amplifier. In this case, for example, each distortion compensation unit 12-k may update each parameter of the k-th learned model so that the error between the input signal xₖ and the received signal zₖ decreases. In this case, for example, each distortion compensation unit 12-k may remove the connection of the network of the k-th learned model so that the error between the input signal xₖ and the received signal zₖ decreases.

Each distortion compensation unit 12-k may acquire a reception signal zₖ from a receiver that receives a radio wave based on the output signal yₖ via a space.

Each distortion compensation unit 12-k may estimate the reception signal zₖ based on the output signal yₖ amplified by the amplifier 143-1 to 143-M and the channel matrix between the phased array transmitter 10 and the receiver. For the estimation, circuits such as the array bank and the sub-matrix used in FIGS. 2 and 3 may be used. The channel matrix may be, for example, a matrix including variation amounts of amplitude and phase of a propagation path (channel) between each transmission antenna and a reception antenna. In this case, each distortion compensation unit 12-k may estimate the channel matrix using, for example, a signal (for example, a pilot signal) known between the phased array transmitter 10 and the receiver.

Each distortion compensation unit 12-k may predict the radio wave propagation characteristic based on, for example, the spatial positional relationship between the phased array transmitter 10 and the receiver and the arrangement of the antennas of the phased array transmitter 10, and estimate the channel matrix based on the predicted radio wave propagation characteristic.

### Others

For example, in Beyond 5G or the like, a phased array transmitter having a large number of antennas and performing beam control is considered to be essential in order to transmit high-quality data to a large number of user terminals at the same time without interference. For example, in satellite communication or the like, a phased array transmitter having a large number of antennas and performing beam control is considered to be indispensable for simultaneously transmitting high-quality data to a large number of ground stations without interference.

In the phased array transmitter, signals originally designed not to interfere are mixed by nonlinear distortion of an amplifier arranged for each antenna, and signal interference occurs. In a case where a conventional digital predistortion (DPD) for multiple beams is used to cancel signal interference due to nonlinear distortion, there is a problem in practical use because of a large amount of calculation.

According to the present disclosure, compensation for nonlinear distortion of an amplifier arranged for each antenna can be appropriately executed. For example, since an output signal in which an inverse characteristic along a physical model of an amplifier arranged for each antenna is effectively added to an input signal can be generated, higher distortion compensation performance can be obtained with a smaller amount of computation.

### Modification

The phased array transmitter 10 may be a device included in one housing, but the phased array transmitter 10 of the present disclosure is not limited thereto. Each unit (e.g., the distortion compensation unit 12) of the phased array transmitter 10 may be achieved by, for example, cloud computing including one or more computers. The distortion compensation unit 12 and the beamforming matrix 14 may be configured as separate devices. Such phased array transmitters 10 are also included in an example of a “phased array transmitter” of the present disclosure.

### Second Example Embodiment

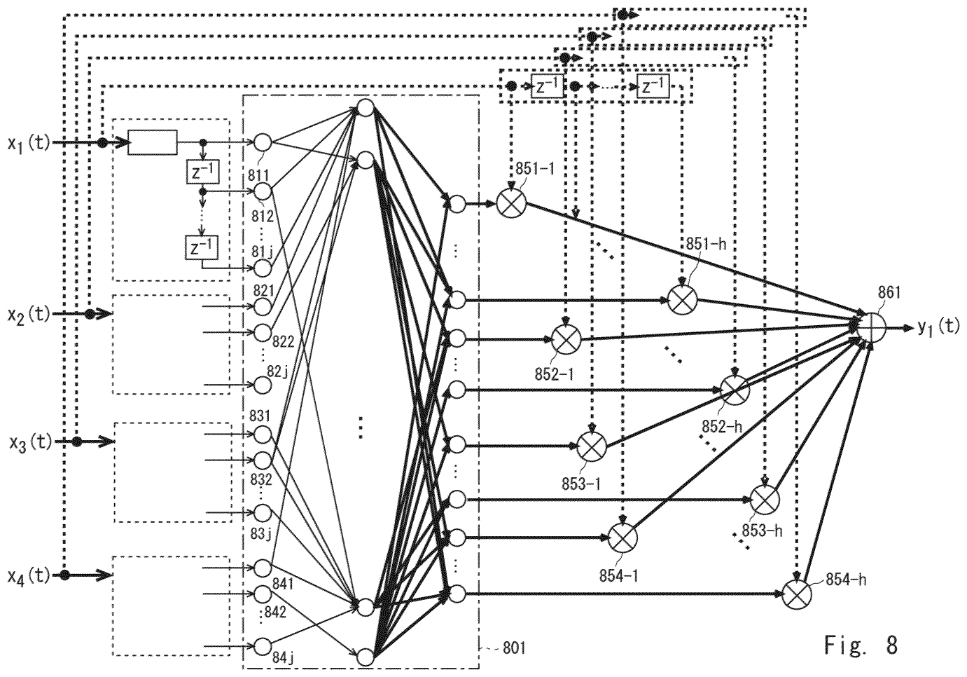

FIG. 8 is a diagram illustrating an example of processing of the distortion compensation unit according to the example embodiment.

In the second example embodiment, the distortion compensation unit 12-k illustrated in FIGS. 6 and 7 described above can be replaced with a distortion compensation unit as illustrated in FIG. 8.

In the example of FIG. 8, the distortion compensation unit 12-1 sets, as the first input data of a first learned model 801, a value 811 which is a result of the specific operation of the value x1(t) of the current time t of the input signal x1. Details of the specific operation will be described later.

The distortion compensation unit 12-1 sets, as second input data of the first learned model 801, a value 812 that is a result of specific operation of a value x1(t−1) at a time point before the current time t of the input signal x1 by a specific period. The distortion compensation unit 12-1 sets, as j-th input data of the first learned model 801, a value 81j which is a result of specific operation of a value x1(t−j) at a time point j (j is an integer equal to or more than 2) times before the current time t of the input signal x1 in a specific period.

For the input signal x2, similarly to the case of the input signal x1, the distortion compensation unit 12-1 sets, as (j+1)th input data, a value 821 which is a result of the specific operation of the value x2(t). The distortion compensation unit 12-1 sets, as (j+2)th input data, a value 822 which is a result of the specific operation of the value x2(t−1). The distortion compensation unit 12-1 sets, as (j+j)th input data, a value 82j which is a result of the specific operation of the value x2(t−j).

Similarly to the case of the input signal x1, for the input signal x3, the distortion compensation unit 12-1 also sets, as (j+j+1)th input data, the value 831 which is a result of the specific operation of the value x3(t). The distortion compensation unit 12-1 sets, as (j+j+2)th input data, a value 832 which is a result of the specific operation of the value x3(t−1). The distortion compensation unit 12-1 sets, as (j+j+j)th input data, a value 83j which is a result of the specific operation of the value x3(t−j).

For the input signal x4, similarly to the case of the input signals x1 to x3, the distortion compensation unit 12-1 sets, as (j+j+j+1)th input data, a value 841 which is a result of the specific operation of the value x4(t). The distortion compensation unit 12-1 sets, as (j+j+j+2)th input data, a value 842 which is a result of the specific operation of the value x4(t−1). The distortion compensation unit 12-1 sets, as (j+j+j+j)th input data, a value 84j which is a result of the specific operation of the value x4(t−j).

The distortion compensation units 12-2 to 12-N are similar to the distortion compensation unit 12-1.

### Specific Operation

The distortion compensation unit 12-k may calculate, for example, the square of the amplitude of the signal as the above-described specific operation. In this case, for example, the value (for example, the value 811 in FIG. 8) as the first input data of the k-th learned model is |x₁(t)|², and the value (for example, the value 812 in FIG. 8) as the second input data is |x₁(t−1)|². The distortion compensation unit 12-k may calculate, for example, the amplitude of the signal as the above-described specific operation. In this case, for example, the value (for example, the value 811 in FIG. 8) as the first input data of the k-th learned model is |x₁(t)|, and the value (for example, the value 812 in FIG. 8) as the second input data is |x₁(t−1)|.

The distortion compensation unit 12-k may calculate at least one of, for example, a real part of a signal, an imaginary part of a signal, a square of a real part of a signal, a square of an imaginary part of a signal, and a multiplication value between a real part and an imaginary part of a signal, as the above-described specific operation.

The distortion compensation unit 12-k may calculate, for example, the square of the amplitude of the linear sum of the input signals x₁ to x_{N} as the above-described specific operation. In this case, for example, the value (for example, the value 811 in FIG. 8) as the first input data of the k-th learned model is |x₁(t)+w₂x₂(t)+. . . +w_{N}x_{N}(t)|², and the value (for example, the value 812 in FIG. 8) as the second input data is |x₁(t−1)+w₂x₂(t−1)+. . . +w_{N}x_{N}(t−1)|². w₂ to w_{N} are specific weighting factors. The distortion compensation unit 12-k may calculate the amplitude of the linear sum of the input signals x₁ to x_{N}, for example, as the above-described specific operation. In this case, for example, the value (for example, the value 811 in FIG. 8) as the first input data of the k-th learned model is |x₁(t)+w₂x₂(t)+. . . +w_{N}x_{N}(t)|, and the value (for example, the value 812 in FIG. 8) as the second input data is |x₁(t−1)+w₂x₂(t−1)+. . . +w_{N}x_{N}(t−1)|.

The distortion compensation unit 12-k may calculate, for example, an inner product or an outer product of the first input signal and the second input signal, in which the I signal and the Q signal of each input signal are regarded as separate components of a vector, as the above-described specific operation. In this case, for example, the value (for example, the value 811 in FIG. 8) to be the first input data of the k-th learned model is Real(x₁(t))×Real(x₂(t))+Imag(x₁(t))×Imag(x₂(t)), and the value (for example, the value 812 in FIG. 8) to be the second input data is Real(x₁(t−1))×Real(x₂(t−1))+Imag(x₁(t−1))×Imag(x₂(t−1)). Real(x) represents a real part of x, and Imag(x) represents an imaginary part of x.

The distortion compensation unit 12-k may calculate, for example, an amplitude value of a linear sum of different signals as the above-described specific operation. Examples of the above-described specific operation can be used in appropriate combination.

Subsequently, each distortion compensation unit 12-k of FIG. 8 outputs, as the output signal yk, a value obtained by adding (summing) values obtained by multiplying each coefficient included in the k-th coefficient group, which is H (in the present disclosure, H is an integer equal to or more than 2) outputs of the k-th learned model, by the time-series signals at the H time points of the input signals x₁ to x_{N} to the DAC 13-k (step S103). As a result, each output signal yk to which the inverse characteristic of the signal interference due to the nonlinear distortion of the amplifier arranged for each antenna is added is output. Therefore, since the inverse characteristic along the physical model of the signal interference due to the nonlinear distortion of the amplifier arranged for each antenna can be effectively added, higher distortion compensation performance can be obtained with a smaller amount of operation. The value of H may be set in advance in the phased array transmitter 10, for example.

Here, as illustrated in FIG. 8, the distortion compensation unit 12-k may add a value obtained by multiplying a time-series signal of the input signal xₖ by each output data (each objective variable) of the k-th learned model.

In the example of FIG. 8, the distortion compensation unit 12-k performs multiplication 851-1 on the first output data of the first learned model 801 by the value x₁(t), and performs multiplication 851-2 on the second output data by the value x₁(t−1). Multiplication 852-1 is performed between the (h+1)th output data and the value x₂(t). Multiplication 85N-1 is performed between the ((N−1)h+1)th output data and the value x_{N}(t). The distortion compensation unit 12-k outputs a value obtained by performing addition 861 on the results of the multiplications 851-1 to 85N-h as the output signal yₖ.

Steps S101 to S102 and steps S104 to S105 are the same as those in the first example embodiment.

While the present disclosure has been particularly shown and described with reference to example embodiments (the first and second example embodiments) thereof, the present disclosure is not limited to these example embodiments. It will be understood by those of ordinary skill in the art that various changes in form and details may be made therein without departing from the spirit and scope of the present disclosure as defined by the claims. And each embodiment can be appropriately combined with other embodiments.

While the present disclosure has been particularly shown and described with reference to example embodiments thereof, the present disclosure is not limited to these example embodiments. It will be understood by those of ordinary skill in the art that various changes in form and details may be made therein without departing from the sprit and scope of the present disclosure as defined by the claims. And each embodiment can be appropriately combined with at least one of embodiments.

Each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

Some or all of the above example embodiments can also be described as the following Supplementary Notes, but are not limited to the following. Some or all of the elements (for example, configurations and functions) described in each supplementary Note dependent on Supplementary Note 1 can also be dependent on independent Supplementary Notes of other categories by the same dependency relationship. Some or all of the elements described in any Supplementary Note may be applied to various types of hardware, software, recording means for recording software, systems, and methods.
(Supplementary Note 1)

A phased array transmitter including:
an input unit that inputs a time-series signal of a first input signal and a time-series signal of a second input signal;
a first distortion compensation unit that outputs a first coefficient group by a first neural network model based on the time-series signal of the first input signal and the time-series signal of the second input signal, and outputs, as a first output signal, a value obtained by multiplying each value included in the time-series signal of the first input signal by each coefficient included in the first coefficient group and then adding the multiplied values; and
a second distortion compensation unit that outputs a second coefficient group by a second neural network model based on the time-series signal of the first input signal and the time-series signal of the second input signal, and outputs, as a second output signal, a value obtained by multiplying each value included in the time-series signal of the second input signal by each coefficient included in the second coefficient group and adding the multiplied values,
in which the first output signal and the second output signal are subjected to phase control and amplification in accordance with each of a plurality of antennas, and are radiated through the plurality of antennas in a wireless manner.
(Supplementary Note 2)

The phased array transmitter according to Supplementary Note 1, in which
the input unit inputs a time-series signal of a third input signal,
the first distortion compensation unit outputs the first coefficient group by the first neural network model based on the time-series signal of the first input signal, the time-series signal of the second input signal, and the time-series signal of the third input signal, and outputs, as the first output signal, a value obtained by multiplying each value included in the time-series signal of the first input signal by each coefficient included in the first coefficient group and adding the multiplied values,
the second distortion compensation unit outputs the second coefficient group by the second neural network model based on the time-series signal of the first input signal, the time-series signal of the second input signal, and the time-series signal of the third input signal, and outputs, as the second output signal, a value obtained by multiplying each value included in the time-series signal of the second input signal by each coefficient included in the second coefficient group and adding the multiplied values,
the phased array transmitter includes a third distortion compensation unit that outputs a third coefficient group by a third neural network model based on the time-series signal of the first input signal, the time-series signal of the second input signal, and the time-series signal of the third input signal, and outputs, as a third output signal, a value obtained by multiplying each value included in the time-series signal of the third input signal by each coefficient included in the third coefficient group and adding the multiplied values, and
the first output signal, the second output signal, and the third output signal are subjected to phase control and amplification in accordance with each of the plurality of antennas, and are radiated through the plurality of antennas in a wireless manner.
(Supplementary Note 3)

The phased array transmitter according to Supplementary Note 1 or 2, in which the first distortion compensation unit causes the first neural network model to output the first coefficient group based on at least one of an amplitude of each signal included in the time-series signal of the first input signal and a square of the amplitude.
(Supplementary Note 4)

The phased array transmitter according to Supplementary Note 1 or 2, in which the first distortion compensation unit causes the first neural network model to output the first coefficient group based on at least one of a real part, an imaginary part, a square of a real part, a square of an imaginary part, and a multiplication value of a real part and an imaginary part of each signal included in the time-series signal of the first input signal.
(Supplementary Note 5)

The phased array transmitter according to Supplementary Note 1 or 2, in which the first distortion compensation unit causes the first neural network model to output the first coefficient group based on at least one of an amplitude of a linear sum of the first input signal and the second input signal, a square of the amplitude, and an inner product or an outer product of the first input signal and the second input signal in which an I signal and a Q signal of each input signal are each regarded as separate components of a vector.
(Supplementary Note 6)

The phased array transmitter according to Supplementary Note 1 or 2, in which the first distortion compensation unit updates the first neural network model based on a first reception signal acquired from a receiver that has received a radio wave based on the first output signal.
(Supplementary Note 7)

The phased array transmitter according to Supplementary Note 1 or 2, in which the first distortion compensation unit updates the first neural network model based on a first reception signal estimated based on the first output signal amplified by an amplifier relevant to each of the plurality of antennas and a channel matrix between the phased array transmitter and a receiver.
(Supplementary Note 8)

The phased array transmitter according to Supplementary Note 1 or 2, in which the first distortion compensation unit removes network connection of the first neural network model based on the first output signal and a first reception signal in a case where a radio wave based on the first output signal is received by a receiver.
(Supplementary Note 9)

A transmission method for causing a phased array transmitter to execute:
inputting a time-series signal of a first input signal and a time-series signal of a second input signal;
outputting a first coefficient group by a first neural network model based on the time-series signal of the first input signal and the time-series signal of the second input signal, and outputting, as a first output signal, a value obtained by multiplying each value included in the time-series signal of the first input signal by each coefficient included in the first coefficient group and then adding the multiplied values; and
outputting a second coefficient group by a second neural network model based on the time-series signal of the first input signal and the time-series signal of the second input signal, and outputting, as a second output signal, a value obtained by multiplying each value included in the time-series signal of the second input signal by each coefficient included in the second coefficient group and adding the multiplied values,
in which the first output signal and the second output signal are subjected to phase control and amplification in accordance with each of a plurality of antennas, and are radiated through the plurality of antennas in a wireless manner.
(Supplementary Note 10)

A program for causing a computer of a phased array transmitter to execute:
inputting a time-series signal of a first input signal and a time-series signal of a second input signal;
outputting a first coefficient group by a first neural network model based on the time-series signal of the first input signal and the time-series signal of the second input signal, and outputting, as a first output signal, a value obtained by multiplying each value included in the time-series signal of the first input signal by each coefficient included in the first coefficient group and then adding the multiplied values; and
outputting a second coefficient group by a second neural network model based on the time-series signal of the first input signal and the time-series signal of the second input signal, and outputting, as a second output signal, a value obtained by multiplying each value included in the time-series signal of the second input signal by each coefficient included in the second coefficient group and adding the multiplied values,
in which the first output signal and the second output signal are subjected to phase control and amplification in accordance with each of a plurality of antennas, and are radiated through the plurality of antennas in a wireless manner.
(Supplementary Note 11)

A phased array transmitter including:
an input unit that inputs a time-series signal of a first input signal and a time-series signal of a second input signal;
a first distortion compensation unit that outputs a first coefficient group by a first neural network model based on the time-series signal of the first input signal and the time-series signal of the second input signal, and outputs, as a first output signal, a value obtained by multiplying each value included in the time-series signal of the first input signal and the time-series signal of the second input signal by each coefficient included in the first coefficient group and then adding the multiplied values; and
a second distortion compensation unit that outputs a second coefficient group by a second neural network model based on the time-series signal of the first input signal and the time-series signal of the second input signal, and outputs, as a second output signal, a value obtained by multiplying each value included in the time-series signal of the first input signal and the time-series signal of the second input signal by each coefficient included in the second coefficient group and adding the multiplied values,
in which the first output signal and the second output signal are subjected to phase control and amplification in accordance with each of a plurality of antennas, and are radiated through the plurality of antennas in a wireless manner.
(Supplementary Note 12)

The phased array transmitter according to Supplementary Note 11, in which
the input unit inputs a time-series signal of a third input signal,
the first distortion compensation unit outputs the first coefficient group by the first neural network model based on the time-series signal of the first input signal, the time-series signal of the second input signal, and the time-series signal of the third input signal, and outputs, as the first output signal, a value obtained by multiplying each value included in the time-series signal of the first input signal, the time-series signal of the second input signal, and the time-series signal of the third input signal by each coefficient included in the first coefficient group and adding the multiplied values,
the second distortion compensation unit outputs the second coefficient group by the second neural network model based on the time-series signal of the first input signal, the time-series signal of the second input signal, and the time-series signal of the third input signal, and outputs, as the second output signal, a value obtained by multiplying each value included in the time-series signal of the first input signal, the time-series signal of the second input signal, and the time-series signal of the third input signal by each coefficient included in the second coefficient group and adding the multiplied values,
the phased array transmitter includes a third distortion compensation unit that outputs a third coefficient group by a third neural network model based on the time-series signal of the first input signal, the time-series signal of the second input signal, and the time-series signal of the third input signal, and outputs, as a third output signal, a value obtained by multiplying each value included in the time-series signal of the first input signal, the time-series signal of the second input signal, and the time-series signal of the third input signal by each coefficient included in the third coefficient group and adding the multiplied values, and
the first output signal, the second output signal, and the third output signal are subjected to phase control and amplification in accordance with each of the plurality of antennas, and are radiated through the plurality of antennas in a wireless manner.

What is claimed is:

1. A phased array transmitter comprising:
at least one memory; and
at least one processor coupled to the memory, wherein
the at least one processor is configured to execute:
inputting a time-series signal of a first input signal and a time-series signal of a second input signal;
outputting a first coefficient group by a first neural network model based on the time-series signal of the first input signal and the time-series signal of the second input signal, and outputting, as a first output signal, a value obtained by multiplying each value included in the time-series signal of the first input signal by each coefficient included in the first coefficient group and then adding the multiplied values; and
outputting a second coefficient group by a second neural network model based on the time-series signal of the first input signal and the time-series signal of the second input signal, and outputting, as a second output signal, a value obtained by multiplying each value included in the time-series signal of the second input signal by each coefficient included in the second coefficient group and adding the multiplied values, and
the first output signal and the second output signal are subjected to phase control and amplification in accordance with each of a plurality of antennas, and are radiated through the plurality of antennas in a wireless manner.

2. The phased array transmitter according to claim 1, wherein
the at least one processor is configured to execute:
inputting a time-series signal of a third input signal;
outputting the first coefficient group by the first neural network model based on the time-series signal of the first input signal, the time-series signal of the second input signal, and the time-series signal of the third input signal, and outputting, as the first output signal, a value obtained by multiplying each value included in the time-series signal of the first input signal by each coefficient included in the first coefficient group and adding the multiplied values;
outputting the second coefficient group by the second neural network model based on the time-series signal of the first input signal, the time-series signal of the second input signal, and the time-series signal of the third input signal, and outputting, as the second output signal, a value obtained by multiplying each value included in the time-series signal of the second input signal by each coefficient included in the second coefficient group and adding the multiplied values; and
outputting a third coefficient group by a third neural network model based on the time-series signal of the first input signal, the time-series signal of the second input signal, and the time-series signal of the third input signal, and outputting, as a third output signal, a value obtained by multiplying each value included in the time-series signal of the third input signal by each coefficient included in the third coefficient group and adding the multiplied values, and
the first output signal, the second output signal, and the third output signal are subjected to phase control and amplification in accordance with each of the plurality of antennas, and are radiated through the plurality of antennas in a wireless manner.

3. The phased array transmitter according to claim 1, wherein the at least one processor is configured to execute outputting a first coefficient group by the first neural network model based on at least one of an amplitude of each signal included in the time-series signal of the first input signal and a square of the amplitude.

4. The phased array transmitter according to claim 1, wherein the at least one processor is configured to execute outputting a first coefficient group by the first neural network model based on at least one of a real part, an imaginary part, a square of a real part, a square of an imaginary part, and a multiplication value of a real part and an imaginary part of each signal included in the time-series signal of the first input signal.

5. The phased array transmitter according to claim 1, wherein the at least one processor is configured to execute outputting a first coefficient group by the first neural network model based on at least one of an amplitude of a linear sum of the first input signal and the second input signal, a square of the amplitude, and an inner product or an outer product of the first input signal and the second input signal in which an I signal and a Q signal of each input signal are each regarded as separate components of a vector.

6. The phased array transmitter according to claim 1, wherein the at least one processor is configured to execute updating the first neural network model based on a first reception signal acquired from a receiver that has received a radio wave based on the first output signal.

7. The phased array transmitter according to claim 1, wherein the at least one processor is configured to execute updating the first neural network model based on a first reception signal estimated based on the first output signal amplified by an amplifier relevant to each of the plurality of antennas and a channel matrix between the phased array transmitter and a receiver.

8. The phased array transmitter according to claim 1, wherein the at least one processor is configured to execute removing network connection of the first neural network model based on the first output signal and a first reception signal in a case where a radio wave based on the first output signal is received by a receiver.

9. A transmission method for causing a phased array transmitter to execute:
inputting a time-series signal of a first input signal and a time-series signal of a second input signal;
outputting a first coefficient group by a first neural network model based on the time-series signal of the first input signal and the time-series signal of the second input signal, and outputting, as a first output signal, a value obtained by multiplying each value included in the time-series signal of the first input signal by each coefficient included in the first coefficient group and then adding the multiplied values; and
outputting a second coefficient group by a second neural network model based on the time-series signal of the first input signal and the time-series signal of the second input signal, and outputting, as a second output signal, a value obtained by multiplying each value included in the time-series signal of the second input signal by each coefficient included in the second coefficient group and adding the multiplied values,
wherein the first output signal and the second output signal are subjected to phase control and amplification in accordance with each of a plurality of antennas, and are radiated through the plurality of antennas in a wireless manner.

10. The transmission method according to claim 9, wherein
the phased array transmitter is configured to execute:
inputting a time-series signal of a third input signal;
outputting the first coefficient group by the first neural network model based on the time-series signal of the first input signal, the time-series signal of the second input signal, and the time-series signal of the third input signal, and outputting, as the first output signal, a value obtained by multiplying each value included in the time-series signal of the first input signal by each coefficient included in the first coefficient group and adding the multiplied values;
outputting the second coefficient group by the second neural network model based on the time-series signal of the first input signal, the time-series signal of the second input signal, and the time-series signal of the third input signal, and outputting, as the second output signal, a value obtained by multiplying each value included in the time-series signal of the second input signal by each coefficient included in the second coefficient group and adding the multiplied values; and
outputting a third coefficient group by a third neural network model based on the time-series signal of the first input signal, the time-series signal of the second input signal, and the time-series signal of the third input signal, and outputting, as a third output signal, a value obtained by multiplying each value included in the time-series signal of the third input signal by each coefficient included in the third coefficient group and adding the multiplied values, and
the first output signal, the second output signal, and the third output signal are subjected to phase control and amplification in accordance with each of the plurality of antennas, and are radiated through the plurality of antennas in a wireless manner.

11. The transmission method according to claim 9, wherein the phased array transmitter is configured to execute outputting a first coefficient group by the first neural network model based on at least one of an amplitude of each signal included in the time-series signal of the first input signal and a square of the amplitude.

12. The transmission method according to claim 9, wherein the phased array transmitter is configured to execute outputting a first coefficient group by the first neural network model based on at least one of a real part, an imaginary part, a square of a real part, a square of an imaginary part, and a multiplication value of a real part and an imaginary part of each signal included in the time-series signal of the first input signal.

13. The transmission method according to claim 9, wherein the phased array transmitter is configured to execute outputting a first coefficient group by the first neural network model based on at least one of an amplitude of a linear sum of the first input signal and the second input signal, a square of the amplitude, and an inner product or an outer product of the first input signal and the second input signal in which an I signal and a Q signal of each input signal are each regarded as separate components of a vector.

14. The transmission method according to claim 9, wherein the phased array transmitter is configured to execute updating the first neural network model based on a first reception signal acquired from a receiver that has received a radio wave based on the first output signal.

15. The transmission method according to claim 9, wherein the phased array transmitter is configured to execute updating the first neural network model based on a first reception signal estimated based on the first output signal amplified by an amplifier relevant to each of the plurality of antennas and a channel matrix between the phased array transmitter and a receiver.

16. The transmission method according to claim 9, wherein the phased array transmitter is configured to execute removing network connection of the first neural network model based on the first output signal and a first reception signal in a case where a radio wave based on the first output signal is received by a receiver.

17. A non-transitory computer-readable medium having stored therein a program for causing a computer of a phased array transmitter to execute:
inputting a time-series signal of a first input signal and a time-series signal of a second input signal;
outputting a first coefficient group by a first neural network model based on the time-series signal of the first input signal and the time-series signal of the second input signal, and outputting, as a first output signal, a value obtained by multiplying each value included in the time-series signal of the first input signal by each coefficient included in the first coefficient group and then adding the multiplied values; and
outputting a second coefficient group by a second neural network model based on the time-series signal of the first input signal and the time-series signal of the second input signal, and outputting, as a second output signal, a value obtained by multiplying each value included in the time-series signal of the second input signal by each coefficient included in the second coefficient group and adding the multiplied values,
wherein the first output signal and the second output signal are subjected to phase control and amplification in accordance with each of the plurality of antennas, and are radiated through the plurality of antennas in a wireless manner.

18. The non-transitory computer-readable medium according to claim 17, wherein
the computer of the phased array transmitter is caused to execute:
inputting a time-series signal of a third input signal;
outputting the first coefficient group by the first neural network model based on the time-series signal of the first input signal, a time-series signal of the second input signal, and the time-series signal of the third input signal, and outputting, as the first output signal, a value obtained by multiplying each value included in the time-series signal of the first input signal by each coefficient included in the first coefficient group and adding the multiplied values;
outputting the second coefficient group by the second neural network model based on the time-series signal of the first input signal, the time-series signal of the second input signal, and the time-series signal of the third input signal, and outputting, as the second output signal, a value obtained by multiplying each value included in the time-series signal of the second input signal by each coefficient included in the second coefficient group and adding the multiplied values; and
outputting a third coefficient group by a third neural network model based on the time-series signal of the first input signal, a time-series signal of the second input signal, and the time-series signal of the third input signal, and outputting, as a third output signal, a value obtained by multiplying each value included in the time-series signal of the third input signal by each coefficient included in the third coefficient group and adding the multiplied values, and
the first output signal, the second output signal, and the third output signal are subjected to phase control and amplification in accordance with each of a plurality of antennas, and are radiated through the plurality of antennas in a wireless manner.

19. The phased array transmitter according to claim 1,
wherein, in addition to the operations recited in claim 1,
each value included in the time-series signal of the first input signal and the time-series signal of the second input signal is further multiplied by each coefficient included in the first coefficient group, and the multiplied values are added to obtain an additional first output signal, and
each value included in the time-series signal of the first input signal and the time-series signal of the second input signal is further multiplied by each coefficient included in the second coefficient group, and the multiplied values are added to obtain an additional second output signal.

20. The phased array transmitter according to claim 19,
wherein, in addition to the operations recited in claim 19,
the at least one processor is further configured to execute:
inputting a time-series signal of a third input signal;
outputting the first coefficient group by the first neural network model based on the time-series signals of the first input signal, the second input signal, and the third input signal, and outputting, as the first output signal, a value obtained by multiplying each value included in the time-series signals of the first input signal, the second input signal, and the third input signal by each coefficient included in the first coefficient group and adding the multiplied values;
outputting the second coefficient group by the second neural network model based on the time-series signals of the first input signal, the second input signal, and the third input signal, and outputting, as the second output signal, a value obtained by multiplying each value included in the time-series signals of the first input signal, the second input signal, and the third input signal by each coefficient included in the second coefficient group and adding the multiplied values;
outputting a third coefficient group by a third neural network model based on the time-series signals of the first input signal, the second input signal, and the third input signal, and outputting, as a third output signal, a value obtained by multiplying each value included in the time-series signals of the first input signal, the second input signal, and the third input signal by each coefficient included in the third coefficient group and adding the multiplied values; and
subjecting the first, second, and third output signals to phase control and amplification in accordance with each of a plurality of antennas, and radiating the phase-controlled and amplified first, second, and third output signals through the plurality of antennas in a wireless manner.
